(19) United States
(12) Patent Application Publication
(10) Pub. No.: US 2026/0173943 A1
(43) Pub. Date: Jun. 18, 2026

(54) A METHOD FOR BONDING A FIRST AND SECOND PLANAR SUBSTRATE

(71) Applicant: TECHNISCHE UNIVERSITEIT EINDHOVEN, Eindhoven (NL)

(72) Inventors: Abdi SALIM, Eindhoven (NL); Tjibbe DE VRIES, Eindhoven (NL); Yuqing JIAO, Eindhoven (NL)

(21) Appl. No.: 18/872,326

(22) PCT Filed: Jun. 9, 2023
(86) PCT No.: PCT/NL2023/050319

§ 371 Date: Dec. 6, 2024

(30) Foreign Application Priority Data
Jun. 9, 2022 (NL) 2032112

(51) Int. Cl. H10W 72/30; H10W 72/00; H10W 90/00

(52) U.S. Cl. CPC H10W 72/354; H10W 72/01365; H10W 72/07338; H10W 72/324; H10W 90/732

(57) ABSTRACT

The present invention relates to a method for bonding a first planar substrate which has a plurality of pillars extending from the substrate to a second planar substrate. The present invention also relates to a bonded planar device. An object of the present invention is to provide a method for bonding planar substrates resulting in accurate substrate-scale post-bonding thickness uniformity and alignment accuracy.

### RELATED APPLICATIONS

The present application claims priority from and the benefit of PCT Application No. PCT/NL2023/050319, filed Jun. 9, 2023, which claims priority from Netherlands Patent Application No. 2032112, filed Jun. 9, 2022. The disclosures of each of these documents is hereby incorporated by reference herein in full.

### FIELD OF THE INVENTION

The present invention relates to a method for bonding a first planar substrate which has a plurality of pillars extending from the substrate to a second planar substrate. The present invention also relates to a bonded planar device.

### BACKGROUND OF THE INVENTION

There are many solutions depending on the nature of bonding. For adhesive bonding using polymers, there are mainly two solutions. The first is creating hard pillars in one wafer and bonding to the other one to lock the two wafers together. These pillars can either be used for interconnections between structures (using copper for example) or they would be made solely for the bonding purpose (using a semiconductor or Aluminium for example). Another method is the creation of rings and disks that interlock during the bonding.

Embodiments generally relate to bonding a first semiconductor to a second semiconductor, wherein the first semiconductor, and/or the second semiconductor, have micro pillars to assist in bonding. An example of bonding a first semiconductor to a second semiconductor is disclosed in US 2014/342479. That US document discloses a method of fabricating a composite semiconductor structure, the method comprising: providing a first substrate comprising a first surface; and a pedestal, wherein the pedestal extends from the first surface to a predetermined height; and the pedestal extends in a direction normal to the first surface; providing a second substrate comprising a first material; attaching an element made of a second material to the pedestal; and bonding the element to the second substrate to form the composite structure, wherein the first surface of the first substrate does not contact the second substrate.

US 2014/117504 relates to a method of releasably attaching a semiconductor wafer to a carrier substrate comprising the steps of providing a semiconductor wafer, providing a carrier substrate having an attachment surface, disposing a temporary bonding composition comprising a curable adhesive material and a release additive between the front side of the semiconductor wafer and the attachment surface of the carrier substrate, and curing the adhesive material to provide a temporary bonding layer, wherein the temporary bonding layer adjacent to the attachment surface of the carrier substrate comprises a relatively lower amount of the release additive and the temporary bonding layer adjacent to the front side of the semiconductor wafer comprises a relatively higher amount of the release additive. The curable adhesive material is chosen from polyarylene oligomers, cyclic-olefin oligomers, arylcyclobutene oligomers, vinyl aromatic oligomers, and mixtures thereof, and the release additive is a polyether compound chosen from the group consisting of polyalkylene oxide homopolymers and polyalkylene oxide copolymers. This US document mentions that a separation of the two substrates is necessary for the completion of the process. The purpose of anchors used here is for enhancing attachment between the two wafers. So these structures enhance strength and prevent detachment in the direction vertical to the wafers. The pillars here do not have the purpose of overcoming lateral shifts and the pillars are fabricated to prevent detachment. Therefore, the pillars do not necessarily require reaching the other substrate since the goal of this US document is to increase the attachment with the other side of the polymer only.

US 2004/041279 relates to a method for attaching a die to a substrate, comprising the steps of placing a plurality of adhesive bumps on the substrate, placing the die on the adhesive bumps, and curing the adhesive bumps, wherein placing the adhesive bumps includes placing an epoxy resin on the substrate. The step of curing the adhesive bumps includes fixing the die to the substrate. This US document discloses an integrated circuit package comprising a substrate, a plurality of adhesive bumps on the substrate, and a die on the plurality of adhesive bumps, wherein the plurality of adhesive bumps includes a high viscosity adhesive material, such as an epoxy resin formed from oxiranes that are identical. The polymer here is chosen mainly to stick well to the substrate because the pillars are needed to join the two wafers with no polymer fill in between, the filling comes after this joining (underfill). The adhesive bumps are mainly used for mechanical strength before the polymer is applied and are mainly chosen to stick well, wherein the polymers must be baked after the two substrates are in contact but no underfill is there. This US document does not disclose that the bonding material fastens the first planar substrate to the second planar substrate but teaches that the pillars are adhesive bumps and are adapted to fix a die to the substrate and the underfill material is introduced into a void between a die and a substrate and connects the die and the substrate. In other words, the adhesive bumps attaches the die to the substrate and the underfill material fills the resulting space or void between the die and the substrate.

WO 2021/043084 relates to a packaging system for a micro-electro-mechanical system device comprising a first substrate and a second substrate, and further comprising a sealing structure arranged between the first substrate and the second substrate. According to this WO document anchors provide a certain spacing between the two substrates to preserve smaller structures. It seems that a polymer underfill can be applied, similar to D2. Such a method only works when complementary locking pillars/structures are present on both wafers.

In addition, US 2015/364441 discloses a method for bonding a first semiconductor, which has a substrate and a plurality of pillars extending from the substrate to a second semiconductor, the method comprising applying a bonding material to the second semiconductor and applying a source of heat and pressing together the second semiconductor and the first semiconductor. Using semiconductor based pillars clearly limit what can be designed/achieved on the geometry, density and eventually performance of the semiconductor devices. It is because the pillars would share the surface and space where the functional devices would be.

A drawback of the method of adhesive bonding using polymers discussed above is that the resulting bonding layer contains void, and their fabrication process is complicated as well. Moreover, these increase dead-space since they are not fabricated from the same material used in bonding. Another drawback of the method of adhesive bonding using polymers discussed above is that it may not be compatible with a wide range of applications, it complicates the bonding process, and it reduces the density of devices that can be integrated since it is considered as dead space for the latter case.

### SUMMARY OF THE INVENTION

An object of the present invention is to provide a method for bonding planar substrates resulting in accurate substrate-scale post-bonding thickness uniformity and alignment accuracy.

Another object of the present invention is to provide a method for bonding planar substrates wherein no dead space is required to fabricate pillars.

Another object of the present invention is to provide a method for bonding planar substrates wherein no additional post-bonding processing steps for pillars are needed.

Another object of the present invention is to provide a method for bonding planar substrates that can be readily integrated in IC and/or PIC process flow with no alteration.

The present invention thus relates to a method for bonding a first planar substrate which has a plurality of pillars extending from the substrate to a second planar substrate, the method comprising:
applying a bonding material to the second planar substrate,
pressing together the second planar substrate and the first planar substrate so that the plurality of pillars puncture the bonding material,
applying a source of heat to ramp up the temperature during bonding whereby the bonding material liquifies and the plurality of pillars of the first planar substrate reach the second planar substrate; and
removing the source of heat so that the bonding material is allowed to cool, wherein the bonding material is a polymer.

The present inventors found that the use of a polymer as bonding material allows for achieving void-free bonding and a homogeneous bonding layer, all with improved post-bonding alignment accuracy and thickness uniformity. The method can therefore be seamlessly integrated in mature process flows without losing layout space or altering the adhesive bonding process step and having extra steps to accommodate the physical presence of these pillars.

The word planar as used here is referred to structures made on the surface of a flat wafer, the dimension of which is much smaller than the total thickness of the wafer. Naturally, the substrates would contain features that increase the topography inwards or outwards since the present type of bonding is mainly done on a processed or semi-processed wafer.

In addition, the present invention encompasses adhesive bonding applications of two planar substrates with a soft-baked adhesive polymer for void-free bonding. It is intended for applications requiring high post-bonding alignment accuracy and/or bonding layer thickness uniformity. In an example pillars are preformed through lithography as anchors for locking the two substrates together and improving these properties. The anchors give mechanical strength after the adhesive polymer is applied to the other substrate. The fabricated pillars have similar physical characteristics to the matrix adhesive film, and therefore require no additional post-bonding rework. Another advantage of the present method is that no additional material is introduced in the bonding interface. Therefore, after bonding it has minimal interruption to the optical and electrical properties of the devices and requires no post-bonding special treatment for the pillars. According to the present method the polymer is added before bonding, i.e. the pillars give mechanical strength only after the bonding material melts and pillars protrude towards the other substrate when heat is applied. The present method functions on the orthogonal direction, i.e. horizontal direction which is parallel to the wafer surface.

In an example the plurality of pillars are prepared form hard-baked polymer pillars.

In an example the bonding material is prepared from a soft-baked polymer.

In an example the plurality of pillars are polymer-based pillars, wherein preferably the polymer-based pillars match the bonding material.

In an example the polymer-based pillars match the adhesive bonding polymer. Using polymer based pillars, there is a full freedom in the design and realization of uninterrupted semiconductor devices. Moreover, the pillar has no or negligible influence on the optical and electrical properties of the semiconductor surface as well.

In an example the bonding material is benzocyclobutene (BCB). The present invention concerns co-integration schemes using adhesive wafer bonding of processed and/or unprocessed semiconductor wafers. Here, the post-bonding alignment accuracy and adhesive thickness uniformity degrades rapidly with increasing bonding thicknesses of the adhesive film. For instance, if BCB is used, the misalignment increases significantly from <2 μm to >30 μ for 1 μm- and 8 μm-thick BCB, respectively. The misalignment can reach values above 100 μm for 16 μm-thick BCB, too. Moreover, the local thickness uniformity degrades from 20% variation in thickness of the desired value to >80% variation for 1 μm- and 8 μm-thick BCB, respectively. This is caused by the reflow of the film that becomes liquid during the bonding process. The latter allows for its redistribution throughout the wafer area leading to non-uniformities. Moreover, the unavoidable presence of shear forces during this bonding leads to misalignments that compromise the co-integration of the processed wafers. The reflow of this polymer is what allows for void-free bonding and higher adhesion, which is important for further processing and mechanical stability.

In an example the second planar substrate has a plurality of pillars extending from the substrate.

In an example the plurality of pillars extending from the substrate enclose structures chosen from the group of waveguides, SOAs, contact pads, CMOS devices and LEDs, or combinations thereof.

The present invention also relates to a bonded planar device, the bonded planar device comprising:
a first planar substrate, the first planar substrate comprising a plurality of pillars, wherein the plurality of pillars extend from the substrate;
a second planar substrate;
and bonding material, wherein:
the bonding material fastens the first planar substrate to the second planar substrate; and the bonding material surrounds each of the plurality of pillars by contacting the one or more sides of each pillar of the plurality of pillars, wherein the bonding material is a polymer.

In an example of the bonded planar device the plurality of pillars are polymer-based pillars.

In an example of the bonded planar device the plurality of pillars reach the second substrate.

In an example of the bonded planar device the plurality of pillars are hard-baked polymer pillars.

In an example of the bonded planar device the bonding material is a soft-baked polymer.

In an example of the bonded planar device the polymer-based pillars match the bonding material.

In an example of the bonded planar device the bonding material is benzocyclobutene (BCB).

In an example of the bonded planar device the second planar substrate has a plurality of pillars extending from the substrate.

A soft-baked polymer has a cross-linking percentage that is low enough for it to reach a low viscous phase while fully cross-linking during the bonding process. A partially-cured polymer has a higher crosslinking percentage, and therefore only becomes gel-like during bonding. Finally, a hard-baked polymer has a cross-linking percentage of ≈100% and is therefore permanently solid. For example, a soft-cured BCB has a cross-linking percentage lower than 35%, while a partially-cured BCB has a percentage between 40% and 75%.

The present method relies on preparing hard-baked polymer pillars on one wafer, and then bonding it to the other wafer that contains the soft-baked polymer.

Here, the pillars easily reach the surface of the other wafer during the reflow process. Therefore, the reflow of the polymer during bonding does not affect the alignment accuracy and uniformity of the bonding layer. The advantage of the present method is that no additional material is introduced in the bonding interface. In an example the pillars are made of the same material as the bonding layers, therefore after bonding it has minimal interruption to the optical and electrical properties of the devices. The idea is that the pillar height is flexible, and the best results are reached when the pillars reach the second substrate. However it is always effective when the pillars extend towards the second wafer.

The pillars are very flexible in dimensions and can be put anywhere on the mask without adding dead space where devices cannot be placed. Finally, the nature of these polymer pillars allows for them to be integrated on any substrate that can be bonded, and methods to fabricate them are seamless. Moreover, the bonding yields a uniform layer whereby the pillars provide a mechanical backbone to fix the two structures at a uniform thickness. Moreover, post-bonding processing of the pillars does not diverge to that of the matrix, which is advantageous in terms of the capacity to adopt the present method in a mature fabrication flow.

The present invention can be used to co-integrate bare substrates or those containing semi-functional/functional devices with maintained high alignment accuracy and bonding layer uniformity. For instance, it can be used for co-integration of photonic wafers made on InP with electronic wafers made of Si or InP. The latter are being investigated to be used in high-speed transceivers.

The present invention thus relates to a method to bond two planar substrates with a soft-baked adhesive polymer, such as soft-baked benzocyclotene BCB, while targeting accurate substrate-scale post-bonding thickness uniformity and alignment accuracy. The envisaged configuration of the present method is realized with a soft-baked polymer layer on one substrate, and hard-baked pillars of the same polymer in the other substrate. As the temperature ramps up during the bonding, the soft-baked polymer liquifies and the pillars easily reach the other substrate. This blocks the two substrates from shifting and prevents vertical reflow with which thickness uniformities increase significantly.

Further areas of applicability of the present disclosure will become apparent from the detailed description provided hereinafter. It should be understood that the detailed description and specific examples, while indicating various embodiments, are intended for purposes of illustration only and are not intended to necessarily limit the scope of the disclosure.

### BRIEF DESCRIPTION OF THE DRAWINGS

FIG. 1 depicts a side view of the two planar substrates after bonding. Pillars are fabricated on substrate one.

FIG. 2 depicts a top view of the two planar substrates after bonding. Only structures in the bonded layer are shown.

FIG. 3 depicts the general process flow for preparing substrate one for bonding.

FIG. 4 depicts the general process flow for preparing substrate two for bonding.

FIG. 5 depicts a side view of the two planar substrates after bonding. Pillars are fabricated on substrate one and two.

FIG. 6 depicts a top view of the two planar substrates with pillars on both sides after bonding.

### DETAILED DESCRIPTION

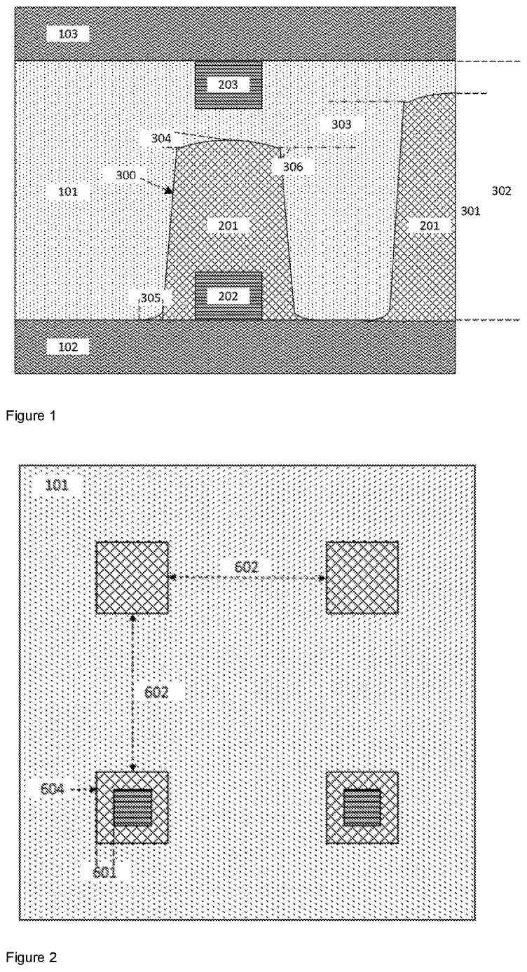

In the next section the reference numbers used in FIGS. 1-6 will be discussed.

Reference number 101 is the adhesive bonding layer. It can be any polymer used for bonding such as BCB benzocyclobutene.

Reference number 102 is the first pre-conditioned substrate used to fabricate pillars. This also includes any other layer used for the adhesive polymer such as dielectrics for better adhesion. The substrate can be a wafer of any size, thickness, or any other planar substrate used to bonding and of any material type.

Reference number 103 is the second substrate. This includes fabricated devices described in (203) and any other layers used for processing the adhesive polymer such as dielectrics for better adhesion. The description of the substrate in 102 applies to 103.

Reference number 201 is the embodiment referred to as pillar Material type: Can be different or the same as the adhesive polymer used for bonding whereby the fabrication process of pillars is done using process 1A. This encompasses photo-sensitive versions of the same polymer where process 1B is used to fabricate the structures. It can also be a dielectric made specifically for this purpose if intended.

Thermal treatment: Can be realized at any thermal budget (temperature×time) where the crosslinking percentage of the polymer translates to higher hardness in the pillars relative to the soft-baked matrix. For instance, the crosslinking range targeting peak hardness and adhesion in BCB is 85-92% which can be used for these pillars.

Positioning on substrate: The pillars can be positioned to enclose structures or to be directly on top of the pre-conditioned substrate (102).

Post-bonding processing: Post-bonding processing of the pillars in the normal configuration is intended to be identical to that of the matrix. Small deviations in the parameters (ex: etch time) can be realized as a results of the different thermal budgets (and composition if desired) of the pillars and matrix.

Physical properties: The mechanical properties of the pillars are intended to be higher than the matrix to achieve the described results. Electrical and optical properties are normally similar unless intended.

Shape: More details on the shape are given in (301-306). However, the vertical profile of pillars is not restricted to this description different profiles can be achieved with the same intended functionalities. Details 301-306 are only provided for illustration.

Reference number 202 is the pre-bonding fabricated structure of any type.

These can be alignment markers used for substrate-to-substrate alignment or structures of any sort, for example: waveguides, SOAs, contact pads or pillars, CMOS devices, LEDs). The structures can be made of the substrate material or layered above. These can be made of any material to deliver their intended functionality.

Pillars can be away from these devices, fully enclosing the devices, or only enclosing part of them ex: contact pads used for interconnections.

Reference number 203 is the structure made on the second substrate (103).

Description of (202) also applies to (203).

Reference number 300 is the interface between pillars and adhesive bonding layer. The pillars before bonding can have an additional interfacial layer to achieve a functionality related to bonding or otherwise. It is also intended that the matrix reflow completely fills (101) to achieve an interface without voids.

Reference number 301 is the intended pillars height for optimal post-bonding alignment accuracy and thickness uniformity. It is normally as close as possible to the height of the matrix. It can also be the same height as the structures in (202) if required.

Reference number 302 is the intended matrix height without counting non-uniformities is normally proportional to the height of devices (202 and 203 and structures included in 102 and 103). It can be in the orders of a micron to several microns where the above-mentioned issues arise.

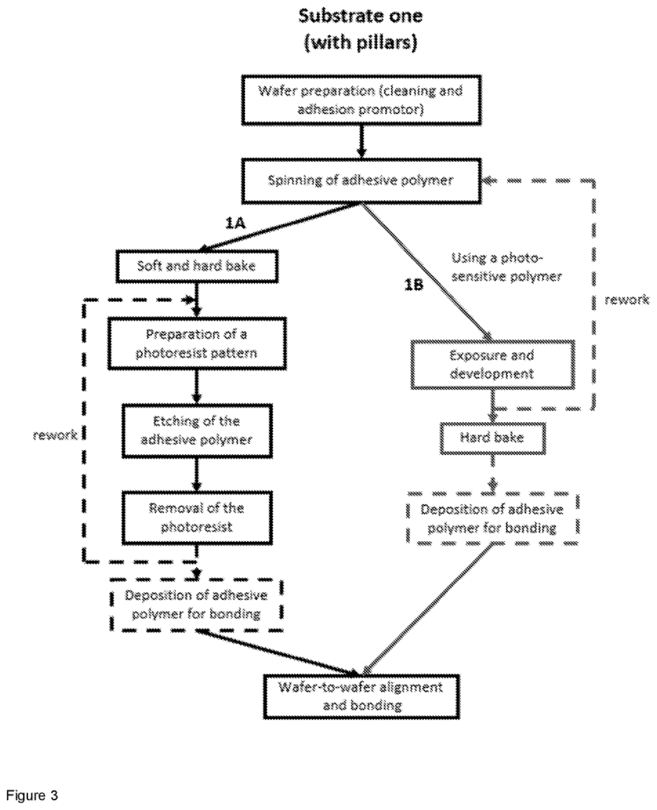

Reference number 303 is the height difference between pillars encompassing devices (202) and other pillars with no devices. This is normally the same height unless required for a certain application. The height difference can be made with multiple lithography's as shown in FIG. 3 (dashed lines) Pillars enclosing devices can be used to protect devices from damage before or during bonding or for any other functionality.

Reference number 304 is the profile of the top surface of pillar: intended shape is flat, other complex shapes resulting from processing are also possible Reference number 305 is the tail on the bottom of pillars, it can be present or not and it is the results of processing or intended

Reference number 306 is the slope of pillars relative to the substrate, it is flexible for any slope either engineered for a specific reason or non-intended.

Reference number 601 is the spatial offset between the intended devices geometry and the intended pillars geometry to fully enclose (cover) devices if desired.

Reference number 602 is the distribution of pillars is flexible on multiple levels that can constitute of cluster or individual pillars. On the devices' cell level, it can be fixed to fit protruding devices, or where cross-matrix interconnections are made, or both. Pillars can also be made in-between mask cells, ex: inside of dice lines. The global distribution of pillars can also be made independently of the mask cells ex: near the substrate edges.

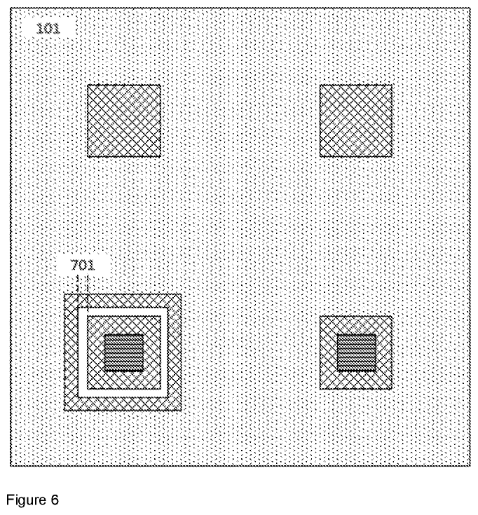

Area between pillars: it therefore follows this distribution. Additionally, it can also contain pillars made from the other substrate for full mechanical interlocking if desired. This is illustrated in FIGS. 5 and 6, whereby substrate two is processed the same as substrate one to fabricate pillars on its side as well. (Process 2) Fill factor: can be of a value that ensures the functionality of the present method given the mechanical properties of the pillars relative to the polymer used for adhesive bonding. The area of pillars therefore follows this factor, pillars can be large or tight where considerations on the functionality of these pillars need to be considered.

The distance between pillars can be in the order of few 100 nanometres to several centimetres whereby the intended critical dimensions are preserved and/or the flow of the adhesive polymer reaches the region in between to avoid creating voids.

Reference number 604 is the mask outline of pillars. It can be any geometrical shape achievable by lithography, spanning for ex: simple circles, polygons, or rings, to complex geometries that contour real devices or part of them.

Reference number 701 is the spatial offset between pillars from substrate one and pillars from substrate two.

Reference number 702 is the intended height of pillars fabricated on substrate two for optimal post-bonding alignment accuracy with mechanical interlocking and thickness uniformity. It is normally as close as possible to the height of the matrix. It can also be the same height as the structures in (202) if required.

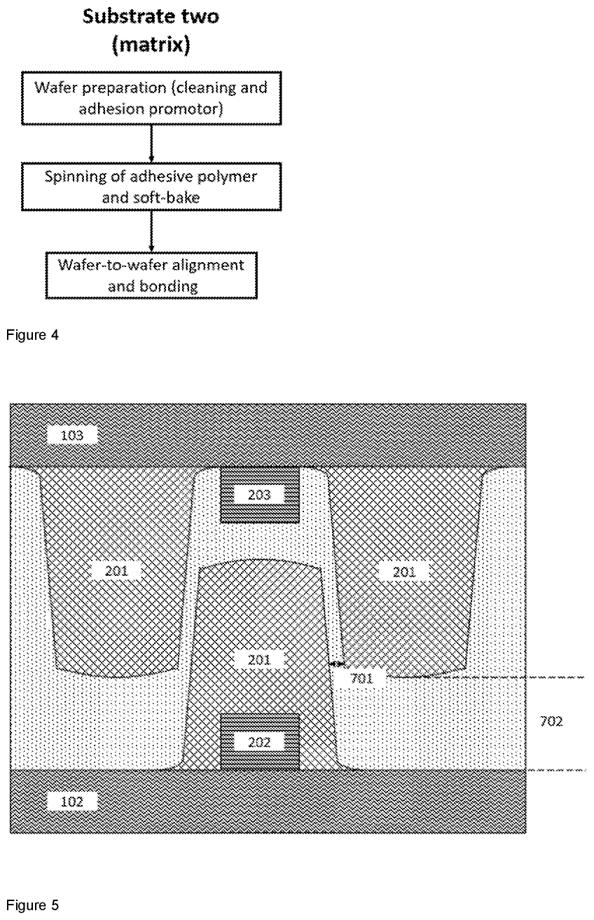

The fabrication process diagram for substrates one and two is shown in FIGS. 3 and 4 respectively. In the normal configuration, pillars are fabricated on substrate one, and the other substrate contains the soft-baked polymer (matrix).

Both wafers are prepared for the deposition and processing of the polymer. For substrate one, if the pillars are intended to be fabricated with the same polymer or a polymer that is not photo-sensitive, the process flow shown in black rectangles and arrows (1A) is adopted. If a photo-sensitive version is adopted, the flow shown in blue rectangles and arrows (1B) is adopted. In both of these flows, if a polymer step-height is needed for a certain functionality, it can be achieved following the dashed lines of each process. The soft- and hard-bake treatments can be varied as discussed. Etching of the polymer in the normal configuration and exposure dose in the photosensitive configuration are normally done until the substrate (102) is reached, this is not restrictive, however.

For substrate two, the polymer is deposited and thermally treated (soft-bake).

The two wafers are aligned with respect to each other.

The bonding can be carried out according to the matrix requirements in terms of thermal treatments. Temperature and force can be applied during the bonding treatment both in the reflow and post-reflow thermal treatment phase, other configurations also apply.

The fabrication flow is not restricted to this description. Other polymers or materials with other flows can be adopted to reach the same functionality. In FIG. 1 and FIG. 5 the protruding features are part of the alignment and improved bonding process.

### Mask Layout for Pillars

For the pillars design, the approach was to verify the capacity of the present method by choosing a real layout used in fabrication of InP-based devices. The mask layout consists of a≈5×5 mm reticle that is repeated throughout the wafer with 40 μm separation. The minimum spacing in the reticle is between two 65×160 rectangles of 11.75 μm. The largest structure in the reticle is an L shaped structure with width of 100 and a perimeter of 1100 μm. More importantly, the fill factor (density of pillars) is ≈20%.

### Experimental Details:

Benzocyclotene (BCB) was chosen as an adhesive layer. To determine the misalignment caused by BCB reflow and the potential of our method, the present inventors carried out experiments by bonding glass-to-glass wafers. The present inventors start with 3″ double-side polished fused silica glass wafers. Next, 10/100 nm thick Ti/Au layers were e-beam deposited and patterned via lift-off for alignment markers, and a 50 nm SiO2 layer was deposited as adhesion promotor. Next, a standard BCB recipe (using Cyclotene 3022-57) was used to spin-coat a single 9 μm layer. A post-bonding thickness around 8.5 μm was measured using a reference InP-on-Si sample after removal of the InP side. In another set of experiments, cyclotene 3022-63 was used to reach 16 μm thickness and tested as well. For the wafer where BCB pillars are fabricated, the present inventors spin-coat and fully hard-crosslink an 8.5 μm-thick BCB layer (and the 16 μm thickness as well) then pattern it using high thickness AZ9260 photoresist via photolithography. Then the pattern was transferred to BCB by O2:CHF3 20:4 plasma RIE etching. The two wafers are then pre-aligned in EVG aligner and bonded in EVG bonder. The full experiment was repeated 3 times without BCB pillars and 2 times with BCB pillars on one wafer. The experiment with 16 μm was repeated 2 times.

To determine the post-bonding BCB thickness uniformity, the present inventors carried out the same bonding experiments, but by bonding InP-to-InP wafers. After the bonding, the top InP wafer (identical to substrate two) was removed in concentrated HCl. The thickness was then mapped over the entire wafer using reflectometry. The present inventors used three wafers without pillars and one with pillars.

The wafer-scale average shifts recorded for the three samples without pillars are (37, 2), (58, 12), and (13, 8) μm in (x,y) coordinates. On the other hand, these values for the samples with pillars are (6.2,4.6) and (3.2,2) μm showing an improved post-bonding misalignment accuracy.

For the 16 μm samples, the average values without pillars of the two samples are (137,47) and (40,18) in μm. The average value with pillars of the two other samples is (1,8) and (3,2) μm. Therefore the present method can be carried out with the same efficiency for 16 μm BCB as compared to 8 μm BCB.

Results on the thickness variations of samples used in this study are shown in Table 1 showing an improved post-bonding BCB thickness uniformity.

TABLE 1
Post-bonding thickness variations from reflectometry maps

| | | Average | Min | Max | | Standard |
|---|---|---|---|---|---|---|
| Sample | | (nm) | (nm) | (nm) | (Min-Max)/Avg | Deviation (nm) |
| Hard baked BCB | | 8544.755 | 8499.023 | 8615.216 | 0.013598 | 27.55241 |
| without bonding | | | | | | |
| InP-InP bonding | 1 | 7219.401 | 4430.974 | 10971.42 | 0.905954 | 2410.519 |
| BCB thickness 8 μm | 2 | 8510.157 | 3833.463 | 11096.18 | 0.853418 | 1604.457 |
| BCB thickness 8 μm. | 3 | 7643.878 | 712.1154 | 10078.95 | 1.225403 | 1938.02 |
| BCB Pillars 8 μm | 4 | 8514.412 | 7735.56 | 9544.547 | 0.212462 | 528.432 |

By looking at the ratio between the minimum and maximum thicknesses recorded over the entire wafers (Table1), an overall improvement of a factor of >4 was recorded for samples with pillars over reference samples.

The interface between the pillars and the matrix was characterized in SEM. All of the interfaces imaged are highly abrupt and contain no voids. This is because of the similar physical properties between the pillars and matrix as well as the good reflow of later during bonding.

The possibility to process the samples with pillars using the same optimized process flow for the matrix was investigated. The present inventors etched the sample with pillars in a O2:CHF3 20:4 plasma. Next, the etch rate of the pillars vs the matrix was calculated by determining the step height using profilometry. The latter is only ≈5% slower than the matrix. It was clear that the morphology inside the pillars is very similar to the matrix. Overall, this experiment shows that a uniform process can be easily achieved if both pillars and matrix need to be processed in the same step.

The refractive index values between BCB processed at the same conditions for the pillars and matrix was investigated. The first estimations yield a refractive index difference <0.03 between pillars and the matrix for wavelengths above 1 μm. This can be further engineered to <0.01 with better selection of the curing parameters of the polymer in pillars.

The present method thus relates to a method for bonding two planar substrates with an adhesive soft-baked polymer. The method yields optimal post-bonding thickness uniformity and alignment accuracy at high thicknesses of the polymer, and without compromising the benefits of adhesive bonding using soft-baked polymers, including void-free bonding and excellent adhesion. Moreover, the fabricated pillars have similar physical characteristics to the matrix adhesive film, and therefore do not add up to the dead space in the mask layout, nor require additional steps to seamlessly integrate them in a mature fabrication flow. This new method will allow for co-integration of more complex structures for photonics and other fields as well.

1. A method for bonding a first planar substrate which has a plurality of pillars extending from the substrate to a second planar substrate, the method comprising:
applying a bonding material to the second planar substrate,
pressing together the second planar substrate and the first planar substrate so that the plurality of pillars puncture the bonding material,
applying a source of heat to ramp up the temperature during bonding whereby the bonding material liquifies and the plurality of pillars of the first planar substrate reach the second planar substrate; and
removing the source of heat so that the bonding material is allowed to cool, wherein the bonding material is a polymer.

2. A method according to claim 1, wherein the plurality of pillars are polymer-based pillars.

3. A method according to claim 2, wherein the plurality of pillars are hard-baked polymer pillars.

4. A method according to claim 1, wherein the bonding material is a soft-baked polymer.

5. A method according to claim 2, wherein polymer-based pillars match the bonding material.

6. A method according to claim 1, wherein the bonding material is benzocyclobutene (BCB).

7. A method according to claim 1, wherein the second planar substrate has a plurality of pillars extending from the substrate.

8. A method according to claim 1, wherein the plurality of pillars extending from the substrate enclose structures chosen from the group of waveguides, SOAs, contact pads, CMOS devices and LEDs.

9. A bonded planar device, the bonded planar device comprising:
a first planar substrate, the first planar substrate comprising a plurality of pillars, wherein the plurality of pillars extend from the substrate;
a second planar substrate;
and bonding material, wherein:
the bonding material fastens the first planar substrate to the second planar substrate;
and the bonding material surrounds each of the plurality of pillars by contacting the one or more sides of each pillar of the plurality of pillars, wherein the bonding material is a polymer.

10. A bonded planar device according to claim 9, wherein the plurality of pillars reach the second substrate.

11. A bonded planar device according to claim 9, wherein the plurality of pillars are polymer-based pillars.

12. A bonded planar device according to claim 11, wherein the plurality of pillars are hard-baked polymer pillars.

13. A bonded planar device according to claim 9, wherein the bonding material is a soft-baked polymer.

14. A bonded planar device according to claim 11, wherein polymer-based pillars match the bonding material.

15. A bonded planar device according to claim 9, wherein the bonding material is benzocyclobutene (BCB).

16. A bonded planar device according to claim 9, wherein the second planar substrate has a plurality of pillars extending from the substrate.
